(19) United States
(12) Patent Application Publication
(10) Pub. No.: US 2015/0107668 A1
(43) Pub. Date: Apr. 23, 2015

(54) SOLAR CELL

(71) Applicant: SANYO Electric Co., Ltd., Osaka (JP)

(72) Inventors: Naoya SOTANI, Hyogo (JP); Masato NAKASU, Osaka (JP); Yutaka KIRIHATA, Osaka (JP)

(21) Appl. No.: 14/580,470

(22) Filed: Dec. 23, 2014

Related U.S. Application Data
(63) Continuation of application No. PCT/JP2012/066759, filed on Jun. 29, 2012.

(51) Int. Cl. H01L 31/0376; H01L 31/0368

(52) U.S. Cl. CPC H01L 31/0376; H01L 31/0368
USPC 136/258

(57) ABSTRACT

Disclosed is a solar cell that comprises a substrate made of a semiconductor material, a first amorphous semiconductor layer placed on one region of the substrate and being of one conductivity type, a substantially intrinsic i-type amorphous semiconductor layer provided to extend from another region of the substrate over onto the first amorphous semiconductor layer, a second amorphous semiconductor layer provided on the i-type amorphous semiconductor layer and being of another conductivity type, a first crystalline semiconductor layer placed between the first amorphous semiconductor layer and the i-type amorphous semiconductor layer and being of the one conductivity type, a second crystalline semiconductor layer placed between the first crystalline semiconductor layer and the i-type amorphous semiconductor layer and being of the other conductivity type, and a third amorphous semiconductor layer placed between the second crystalline semiconductor layer and the i-type amorphous semiconductor layer and being of the other conductivity type.

### CROSS REFERENCE TO RELATED APPLICATIONS

This application is a continuation application of International Application No. PCT/JP2012/066759, filed on Jun. 29, 2012, entitled “SOLAR CELL”, the entire contents of which are incorporated herein by reference.

### TECHNICAL FIELD

The disclosure relates to a solar cell.

### BACKGROUND ART

As a solar cell, which can improve electric conversion efficiency, PCT International Publication WO2010/098445A1 (Patent Document 1) describes a back contact solar cell having both of a p-side electrode and an n-side electrode provided on the back-surface side. The solar cell described in Patent Document 1 has a first semiconductor layer provided on a first region of one main surface of a substrate made of a semiconductor material and a second semiconductor layer provided on a second region of the one main surface. One of the first and second semiconductor layers is of a p-type, and the other one is of an n-type. The second semiconductor layer is provided to extend from the second region over onto the first semiconductor layer. In the first region, a recombination layer is provided between the first semiconductor layer and the second semiconductor layer. This recombination layer is a layer for forming a recombination interface where holes and electrons recombine.

### SUMMARY OF THE INVENTION

There is a demand for further improvement in the photoelectric conversion efficiency of a solar cell.

A solar cell according to an embodiment includes a substrate made of a semiconductor material, a first amorphous semiconductor layer, a substantially intrinsic i-type amorphous semiconductor layer, a second amorphous semiconductor layer, a first crystalline semiconductor layer, a second crystalline semiconductor layer, and a third amorphous semiconductor layer. The first amorphous semiconductor layer is placed on one region of the substrate. The first amorphous semiconductor layer is of one conductivity type. The i-type amorphous semiconductor layer is provided to extend from another region of the substrate over onto the first amorphous semiconductor layer. The second amorphous semiconductor layer is provided on the i-type amorphous semiconductor layer. The second amorphous semiconductor layer is of another conductivity type. The first crystalline semiconductor layer is placed between the first amorphous semiconductor layer and the i-type amorphous semiconductor layer. The first crystalline semiconductor layer is of the one conductivity type. The second crystalline semiconductor layer is placed between the first crystalline semiconductor layer and the i-type amorphous semiconductor layer. The second crystalline semiconductor layer is of the other conductivity type. The third amorphous semiconductor layer is placed between the second crystalline semiconductor layer and the i-type amorphous semiconductor layer. The third amorphous semiconductor layer is of the other conductivity type.

### BRIEF DESCRIPTION OF THE DRAWINGS

FIG. 1 is a schematic sectional view of a solar cell according to one embodiment.

FIG. 2 is a schematic sectional view of a solar cell according to a reference example.

FIG. 3 is a band diagram illustrating part of an energy level in a solar cell according to the reference example.

FIG. 4 is a band diagram illustrating part of an energy level in a first example.

FIG. 5 is a band diagram illustrating part of an energy level in a second example.

### EMBODIMENTS

Hereinafter, embodiments are described. It should be noted that the following embodiments are provided just for illustrative purposes. The invention should not be limited at all to the following embodiments.

In the drawings referred to in the embodiments and other parts, components having substantially the same function are referred to with the same reference numeral. In addition, the drawings referred to in the embodiments and other parts are illustrated schematically, and the dimensional ratio and the like of objects depicted in the drawings are different from those of actual objects in some cases. The dimensional ratio and the like of objects are also different among the drawings in some cases. The specific dimensional ratio and the like of objects should be determined with the following description taken into consideration.

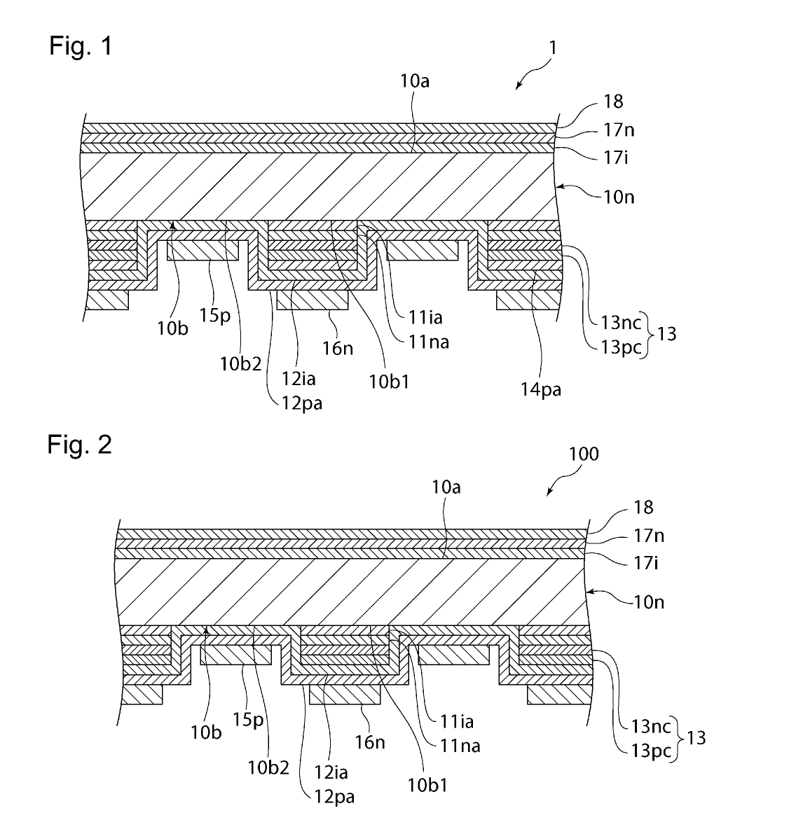

As illustrated in FIG. 1, solar cell 1 has substrate 10n made of a semiconductor material. Substrate 10n has n-type or p-type conductivity. In this embodiment, specifically, substrate 10n is n-type conductivity. Substrate 10n can be formed from, for example, an n-type crystalline semiconductor material or the like. Specifically, substrate 10n can be formed from, for example, n-type crystalline silicon. Note that a crystalline semiconductor material includes a single-crystal semiconductor material and a polycrystalline semiconductor material and that crystalline silicon includes single-crystal silicon and polycrystalline silicon.

Substrate 10n has first main surface 10a for main light reception and second main surface 10b. First main surface 10a is located on the light-receiving surface side. The “light-receiving surface” refers to a main surface for main light reception out of the two main surfaces.

On first main surface 10a, semiconductor layer 17i, semiconductor layer 17n, and protection layer 18 are provided in the order mentioned. Semiconductor layer 17i is made of a substantially intrinsic i-type semiconductor material. Semiconductor layer 17i can be formed from, for example, i-type amorphous silicon. Semiconductor layer 17i preferably has a thickness which does not substantially contribute to power generation (e.g., about zero point several nanometers to 25 nm). Like substrate 10n, semiconductor layer 17n has n-type conductivity. Semiconductor layer 17n can be formed from, for example, n-type amorphous silicon. Protection layer 18 can be formed from, for example, silicon nitride or the like. Protection layer 18 may have a function of suppressing surface reflection of incident light, in addition to a function of protecting semiconductor layer 17n.

First amorphous semiconductor layer 11na is placed above first region 10b1 of second main surface 10b. First amorphous semiconductor layer 11na has the same conductivity as substrate 10n. Specifically, first amorphous semiconductor layer 11na has n-type conductivity, although first amorphous semiconductor layer 11na may be of a different conductivity type from substrate 10n. First amorphous semiconductor layer 11na can be formed from, for example, n-type amorphous silicon.

Substantially intrinsic i-type amorphous semiconductor layer 11ia is provided between first amorphous semiconductor layer 11na and second main surface 10b. I-type amorphous semiconductor layer 11ia has a thickness which substantially does not contribute to power generation (e.g., about zero point several nanometers to 25 nm). I-type amorphous semiconductor layer 11ia can be formed from, for example, i-type amorphous silicon.

Substantially intrinsic i-type amorphous semiconductor layer 12ia is provided on second region 10b2 of second main surface 10b, second region 10b2 being at least part of a region excluding first region 10b1. Second amorphous semiconductor layer 12pa is provided on i-type amorphous semiconductor layer 12ia. I-type amorphous semiconductor layer 12ia and second amorphous semiconductor layer 12pa are provided to extend from second region 10b2 over onto first amorphous semiconductor layer 11na. Thus, in first region 10b1, first amorphous semiconductor layer 11na and second amorphous semiconductor layer 12pa are stacked.

I-type amorphous semiconductor layer 12ia can be formed from, for example, i-type amorphous silicon. Preferably, i-type amorphous semiconductor layer 12ia has a thickness which substantially does not contribute to power generation (e.g., about zero point several nanometers to 25 nm). Second amorphous semiconductor layer 12pa is of a different conductivity type from substrate 10n. Specifically, second amorphous semiconductor layer 12pa has p-type conductivity. Second amorphous semiconductor layer 12pa can be formed from, for example, p-type amorphous silicon.

Crystalline semiconductor layer 13 is provided between first amorphous semiconductor layer 11na and i-type amorphous semiconductor layer 12ia. Crystalline semiconductor layer 13 is a layer for recombining holes and electrons. Crystalline semiconductor layer 13 has a defect level that can act as a recombination center. This facilitates recombination of electrons and holes in crystalline semiconductor layer 13. Consequently, current flows through crystalline semiconductor layer 13.

For example, crystalline semiconductor layer 13 has a thickness of preferably about 2 nm to 60 nm, or more preferably, 2 nm to 30 nm.

Crystalline semiconductor layer 13 has first crystalline semiconductor layer 13nc and second crystalline semiconductor layer 13pc. First crystalline semiconductor layer 13nc is provided on first amorphous semiconductor layer 11na. First crystalline semiconductor layer 13nc is in contact with first amorphous semiconductor layer 11na. First crystalline semiconductor layer 13nc is of the same conductivity type as first amorphous semiconductor layer 11na. Specifically, first crystalline semiconductor layer 13nc has n-type conductivity. First crystalline semiconductor layer 13nc can be formed from, for example, n-type microcrystalline silicon. For example, first crystalline semiconductor layer 13nc has a thickness of preferably about 1 nm to 30 nm, or more preferably, 1 nm to 15 nm.

Note that a microcrystalline semiconductor layer is a layer containing multiple semiconductor crystal grains. A microcrystalline semiconductor layer includes a layer made substantially only of semiconductor crystal grains. Further, a microcrystalline semiconductor layer may have a semiconductor amorphous region in addition to semiconductor crystal grains.

Second crystalline semiconductor layer 13pc is provided between first crystalline semiconductor layer 13nc and i-type amorphous semiconductor layer 12ia. Second crystalline semiconductor layer 13pc is of a different conductivity type from first crystalline semiconductor layer 13nc. Specifically, second crystalline semiconductor layer 13pc has p-type conductivity. Second crystalline semiconductor layer 13pc can be formed from, for example, p-type microcrystalline silicon. For example, second crystalline semiconductor layer 13pc has a thickness of preferably about 1 nm to 30 nm, or more preferably, 1 nm to 15 nm.

In first region 10b1, n-side electrode 16n is provided on second amorphous semiconductor layer 12pa. On the other hand, in second region 10b2, p-side electrode 15p is provided on second amorphous semiconductor layer 12pa. Electrodes 15p, 16n can be formed from, for example, a conductive material containing at least one kind of metals such as Ag, Cu, W, Ti, and Al.

Solar cell 1 has third amorphous semiconductor layer 14pa provided between second crystalline semiconductor layer 13pc and i-type amorphous semiconductor layer 12ia. Third amorphous semiconductor layer 14pa is of the same conductivity type as second crystalline semiconductor layer 13pc. Specifically, third amorphous semiconductor layer 14pa has p-type conductivity. Third amorphous semiconductor layer 14pa can be formed from, for example, p-type amorphous silicon. For example, third amorphous semiconductor layer 14pa has a thickness of preferably about 0.5 nm to 30 nm, or more preferably, 2 nm to 15 nm.

The ease of flow of current through a semiconductor layer correlates with the carrier concentration of the semiconductor layer. The lower the carrier concentration of a semiconductor layer, the lower the ease of flow of current through the semiconductor layer. Generally, an i-type semiconductor layer has lower carrier concentration than a p-type semiconductor layer or an n-type semiconductor layer. Thus, to increase the ease of flow of current, the carrier concentration of the i-type semiconductor layer needs to be increased.

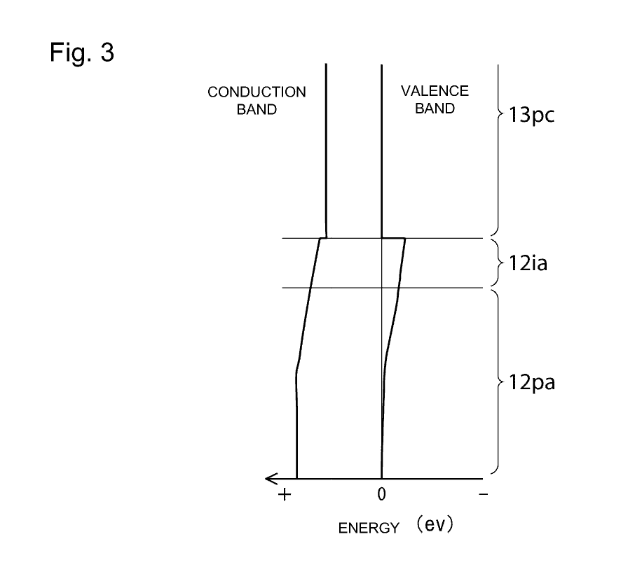

If, as illustrated in FIG. 2, second crystalline semiconductor layer 13pc and i-type amorphous semiconductor layer 12ia are in direct contact with each other without third amorphous semiconductor layer 14pa interposed between them, band offset occurs between i-type amorphous semiconductor layer 12ia and second crystalline semiconductor layer 13pc, as illustrated in FIG. 3. For this reason, in order for carriers to move from second crystalline semiconductor layer 13pc or second amorphous semiconductor layer 12pa to i-type amorphous semiconductor layer 12ia, the carriers need to go over this band offset or band bending accompanying the band offset. Thus, it is hard for the carriers to move from second crystalline semiconductor layer 13pc or second amorphous semiconductor layer 12pa to i-type amorphous semiconductor layer 12ia. Consequently, i-type amorphous semiconductor layer 12ia has low carrier concentration.

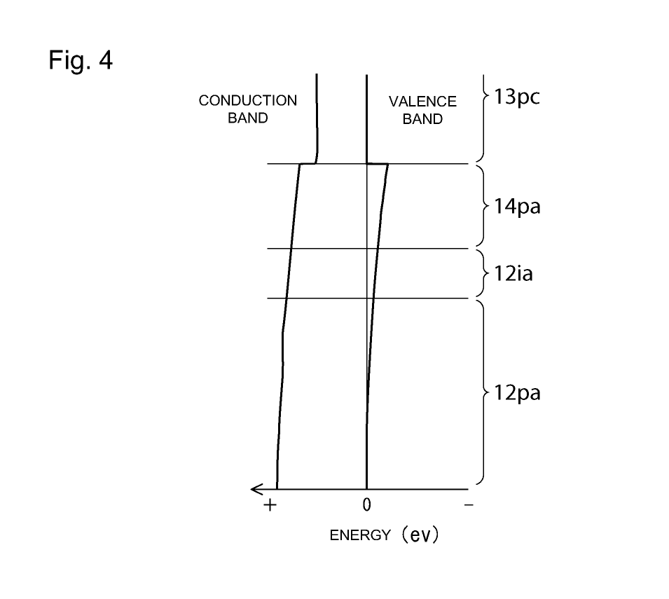

On the other hand, in solar cell 1, third amorphous semiconductor layer 14pa having the same conductivity type as second crystalline semiconductor layer 13pc is provided between second crystalline semiconductor layer 13pc and i-type amorphous semiconductor layer 12ia. In this case, as illustrated in FIG. 4, band offset is located not between second crystalline semiconductor layer 13pc and i-type amorphous semiconductor layer 12ia, but between second crystalline semiconductor layer 13pc and third amorphous semiconductor layer 14pa. Thus, i-type amorphous semiconductor layer 12ia does not have a large drop at the end of valence band. For this reason, it is easy for carriers to move from third amorphous semiconductor layer 14pa or second amorphous semiconductor layer 12pa to i-type amorphous semiconductor layer 12ia. Consequently, i-type amorphous semiconductor layer 12ia has high carrier concentration. Thus, electrical resistance between first amorphous semiconductor layer 11na and n-side electrode 16n can be lowered. As a result, photoelectrical conversion efficiency can be improved.

In an actual experiment, a contact resistance between substrate 10n and n-side electrode 16n is 0.092 Ωcm² for solar cell 1, whereas a contact resistance between substrate 10n and n-side electrode 16n is 0.74 Ωcm² for a solar cell configured substantially the same as solar cell 1 except for not having third amorphous semiconductor layer 14pa. This result makes it apparent that provision of third amorphous semiconductor layer 14pa can decrease electrical resistance.

Even if the valence band has an energy gap in second amorphous semiconductor layer 12pa, the electrical resistance of second amorphous semiconductor layer 12pa presumably does not increase so much because current flows due to, for example, tunneling effect or the like.

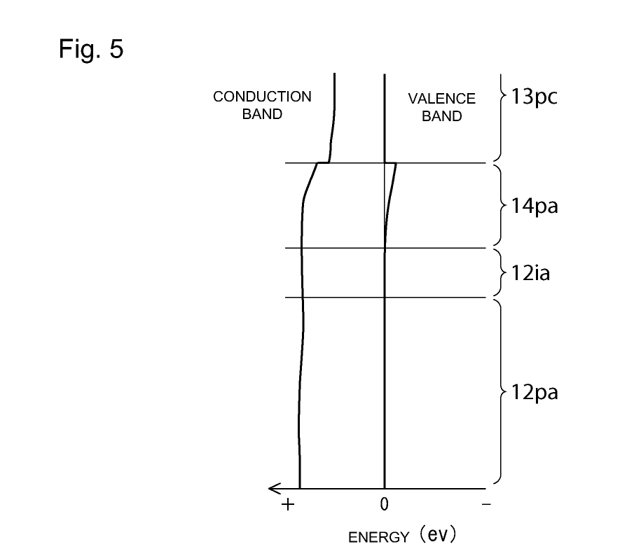

From the perspective of improving photoelectric conversion efficiency more, third amorphous semiconductor layer 14pa preferably has high dopant concentration. In this case, as illustrated in FIG. 5, the energy drop caused at the end of the valence band by the band offset between second crystalline semiconductor layer 13pc and third amorphous semiconductor layer 14pa is suppressed even more. Thus, the drop at the end of the valence bad in i-type amorphous semiconductor layer 12ia can be reduced more, so that high carrier concentration can be maintained. As a result, the electrical resistance between first amorphous semiconductor layer 11na and n-side electrode 16n can be reduced even more. Thus, electrical conversion efficiency can be improved more.

Although solar cell 1 is aback contact solar cell in this embodiment, the invention is not limited to such a configuration. The solar cell according to the invention may be a solar cell in which a p-side electrode is provided on the one main surface side of a substrate made of a semiconductor material, and an n-side electrode is provided on the other main surface side of the substrate.

In this way, the embodiments described above can provide a solar cell with improved photoelectric conversion efficiency.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

1. A solar cell comprising:
a substrate;
a first amorphous semiconductor layer arranged at a first region of the substrate and being of a first conductivity type;
a substantially intrinsic i-type amorphous semiconductor layer provided to extend from a second region of the substrate over onto the first amorphous semiconductor layer;
a second amorphous semiconductor layer arranged at the i-type amorphous semiconductor layer and being of a second conductivity type;
a first crystalline semiconductor layer arranged between the first amorphous semiconductor layer and the i-type amorphous semiconductor layer and being of the first conductivity type;
a second crystalline semiconductor layer arranged between the first crystalline semiconductor layer and the i-type amorphous semiconductor layer and being of the second conductivity type; and
a third amorphous semiconductor layer arranged between the second crystalline semiconductor layer and the i-type amorphous semiconductor layer and being of the second conductivity type.

2. The solar cell according to claim 1, wherein
the third amorphous semiconductor layer has a thickness ranging from 0.5 nm to 30 nm.

3. The solar cell according to claim 1, wherein
the first and second amorphous semiconductor layers are arranged at one main surface of the substrate.

4. The solar cell according to claim 1, wherein
the third amorphous semiconductor layer has a thickness ranging from 2 nm to 15 nm.

5. The solar cell according to claim 1, further comprising:
a second substantially intrinsic i-type amorphous semiconductor layer provided between the first amorphous semiconductor layer and the substrate.

6. The solar cell according to claim 1, wherein
the first crystalline semiconductor layer has a thickness of about 1 nm to 30 nm.

7. The solar cell according to claim 1, wherein
the first crystalline semiconductor layer has a thickness of about 1 nm to 15 nm.

8. The solar cell according to claim 1, wherein
the second crystalline semiconductor layer has a thickness of preferably about 1 nm to 30 nm.

9. The solar cell according to claim 1, wherein
the second crystalline semiconductor layer has a thickness of preferably about 1 nm to 15 nm.

10. The solar cell according to claim 1, wherein
the first and second crystalline semiconductor layers are made of a microcrystalline semiconductor.

11. The solar cell according to claim 10, wherein
the microcrystalline semiconductor is made substantially of semiconductor crystal grains.

12. The solar cell according to claim 10, wherein
the second crystalline semiconductor includes a semiconductor amorphous region and a semiconductor crystal grains region.
